(19) United States
(12) Patent Application Publication
(10) Pub. No.: US 2022/0018707 A1
(43) Pub. Date: Jan. 20, 2022

(54) Method and Device for Monitoring a Circuit Breaker

(71) Applicant: ABB Schweiz AG, Baden (CH)

(72) Inventors: Niya Chen, Beijing (CN); Jiayang Ruan, Beijing (CN)

(73) Assignee: ABB Schweiz AG, Baden (CH)

(21) Appl. No.: 17/299,358

(22) PCT Filed: Dec. 24, 2018
(86) PCT No.: PCT/CN2018/123232

§ 371 Date: Jun. 3, 2021

(51) Int. Cl. G01H 1/06; G01R 31/327

(52) U.S. Cl. CPC G01H 1/06; G01R 31/3275

(57) ABSTRACT

Methods for monitoring a circuit breaker include detecting at least one operation of a circuit breaker to obtain at least one vibration signal of the circuit breaker. Each vibration signal is represented as one-dimensional data of a vibration amplitude over time during the operation of the circuit breaker. The vibration signal is transformed to two-dimensional frequency-time data. The transformed frequency-time data is compared with benchmark data characterizing the at least one operation of the circuit breaker. A health condition is determined of the circuit breaker at least in part based on the comparison. Both the frequency component and the time component in the detected test vibration signals are considered in condition determination of the circuit breaker. The condition can be determined with high accuracy.

### FIELD

Example embodiments of the present disclosure generally relate to a circuit breaker and more particularly, to a method and device for monitoring of a circuit breaker.

### BACKGROUND

Circuit breakers are widely used in an electrical grid. Circuit breakers are designed to protect an electrical circuit or electrical devices from damage caused by excess current from an overload or short circuit. When circuit breakers fail to operate during such an adverse electrical condition, catastrophic results may arise. However, the circuit breakers may be subject to various failures over time, which will threaten security of the electrical circuit. It is desirable to carry out condition monitoring of the circuit breakers so as to track the operation conditions of the circuit breakers and to enable the indication of potential failure occurrences and predictive maintenance.

Circuit breakers are generally enclosed in a casing and their conditions cannot be easily monitored. Conventional circuit breaker monitoring systems typically comprises a measuring device that measures parameters associated with the circuit breaker. However, such a system cannot provide comprehensive condition monitoring and diagnosis of the circuit breakers since the type of failures that the system can detect is limited.

For example, US2017/045481 A1 discloses a system for monitoring a circuit breaker. It comprises a vibration sensor to measure actual component characteristics. Vibration signals are segmented and features, such as total energy of each collision in mechanism, are extracted. The extracted features are used to determine the condition of the circuit breaker. In this solution, designated features are extracted to reflect certain kinds of condition change, hence only limited types of failures can be detected.

US2014/069195 A1 discloses a circuit breaker analyzer for determining the mechanical condition of a circuit breaker. A smartphone is coupled to measure mechanical vibrations generated at a surface of the device and then such measured values is comparing to a known signature of mechanical vibrations. The signature is, for example, the duration or time between the two peaks generated by the mechanical vibrations from the opening of the circuit breaker. In this solution, the signature for comparison is also only specific features. In some circumstances, failure conditions of the circuit breaker cannot be recognized. In other circumstances, healthy conditions of the circuit breakers are wrongly determined as failure conditions.

### SUMMARY

Example embodiments of the present disclosure propose a solution for circuit breaker condition monitoring.

In a first aspect, example embodiments of the present disclosure provide a method for monitoring a circuit breaker. The method comprises: detecting at least one operation of a circuit breaker to obtain at least one vibration signal of the circuit breaker, each vibration signal being represented as one-dimensional data of a vibration amplitude over time during the operation of the circuit breaker; transforming the vibration signal to two-dimensional frequency-time data; comparing the transformed frequency-time data with benchmark data characterizing the at least one operation of the circuit breaker; and determining a health condition of the circuit breaker at least in part based on the comparison.

In the method, the detected one-dimensional vibration signals are transformed into two-dimensional frequency-time data and the comparison for condition determination is performed between two-dimensional frequency-time data and benchmark data. Contrary to conventional methods, all frequency components at different time in the detected vibration signals are considered in condition determination of the circuit breaker. Consequently, the condition can be determined with high accuracy.

In some embodiments, the transforming comprises: identifying a noise signal component in the vibration signal; and de-nosing the vibration signal by removing the identified noise. Accordingly, noise signals may be removed from the vibration signals.

In some embodiments, the transforming comprises: identifying a delay in the vibration signal; and synchronizing the vibration signal by removing the delay. Accordingly, the vibration signal may be synchronized.

In some embodiments, the transforming comprises applying at least one of the following onto the vibration signal: a wavelet transform, a Short-time Fourier transform, and a Wigner-Ville distribution.

In some embodiments, the comparing comprises: determining a metric including at least one of the following: a distance between the two-dimensional frequency-time data and the benchmark data, and a correlation coefficient between the two-dimensional frequency-time data and the benchmark data; and determining a similarity between the two-dimensional frequency-time data and the benchmark data based on the metric.

In some embodiments, the comparing comprises: processing the two-dimensional frequency-time data using image processing methods, and determining similarity between the two-dimensional frequency-time data and the benchmark data. For example, the two-dimensional frequency-time data can be treated as an image and thus can be processed using image processing methods.

In some embodiments, the benchmark data is generated by: detecting at least one operation of a normal circuit breaker to obtain at least one normal vibration signal of the circuit breaker; transforming the at least one normal vibration signals to two-dimensional frequency-time data; and generating the benchmark data based on the transformed normal frequency-time data. In this case, the benchmark data is obtained from normal or healthy circuit breaker. Accordingly, only operations of healthy circuit breaker are used to create benchmark data. It is unnecessary to create benchmark data for operations of unhealthy circuit.

In some embodiments, the normal operation of the circuit breaker comprises closing and/or opening of the circuit breaker.

In some embodiments, the detecting comprises detecting a plurality of vibration signals; and wherein the comparing comprises comparing the plurality of vibration signals with the respective benchmark data. In some embodiments, the determining comprises excluding false determination using a filtering window. Accordingly, the reliability of condition determination is further improved.

In a second aspect, example embodiments of the present disclosure provide a device for monitoring a circuit breaker comprising: a sensor configured to sense a vibration during operation of the circuit breaker; and at least one processor communicatively coupled to the sensor and configured to perform the method according to any of the first aspect.

In a third aspect, example embodiments of the present disclosure provide a computer readable medium having instructions stored thereon, the instructions, when executed on at least one processor, cause the at least one processor to perform the method according to any of the first aspect.

In a fourth aspect, example embodiments of the present disclosure provide a computer program product being tangibly stored on a computer readable storage medium and comprising instructions which, when executed on at least one processor, cause the at least one processor to perform the method according to any of the first aspect.

In a fifth aspect, example embodiments of the present disclosure provide an Internet of Things (IoT) system. The system comprise: a circuit breaker; and a device for circuit breaker condition monitoring according the second aspect.

### BRIEF DESCRIPTION OF THE DRAWINGS

Through the following detailed descriptions with reference to the accompanying drawings, the above and other objectives, features and advantages of the example embodiments disclosed herein will become more comprehensible. In the drawings, several example embodiments disclosed herein will be illustrated in an example and in a non-limiting manner, wherein:

FIG. 1 shows a block diagram of a device for monitoring a circuit breaker 100 in accordance with embodiments of the present disclosure;

FIG. 2 illustrate a flowchart of a method for monitoring a circuit breaker in accordance with some example embodiments of the present disclosure;

FIG. 3 illustrates a one-dimensional test vibration signal of a vibration amplitude over time sampled during operation of the circuit breaker in accordance with some example embodiments of the present disclosure, with noise signal also illustrated;

FIG. 4a illustrates a schematic view of a reference test vibration signal without delay in accordance with some example embodiments of the present disclosure,

FIG. 4b illustrates a schematic view of a test vibration signal with delay in accordance with some example embodiments of the present disclosure,

FIG. 4c illustrates the signal of FIG. 4b after synchronization;

FIG. 5a illustrates a one-dimensional vibration signal of a vibration amplitude over time of a normal circuit breaker in accordance with some example embodiments of the present disclosure;

FIG. 5b illustrates a two-dimensional frequency-time image transformed from the signal of FIG. 5a by wavelet transform;

FIG. 6a illustrates a one-dimensional vibration signal of a vibration amplitude over time of a defective circuit breaker in accordance with some example embodiments of the present disclosure;

FIG. 6b illustrates a two-dimensional frequency-time image transformed from the signal of FIG. 6a by wavelet transform; and

Throughout the drawings, the same or corresponding reference symbols refer to the same or corresponding parts.

### DETAILED DESCRIPTION

The subject matter described herein will now be discussed with reference to several example embodiments. These embodiments are discussed only for the purpose of enabling those skilled persons in the art to better understand and thus implement the subject matter described herein, rather than suggesting any limitations on the scope of the subject matter.

It is to be understood that although an example embodiments of the present disclosure is illustrated below for use with circuit breakers, the present disclosure may be implemented using any number of techniques, including currently known and future developed, to analyze mechanical vibrations generated during operation of any machine, device, or equipment. The present invention should in no way be limited to the example embodiments, drawings, and techniques illustrated below, including the exemplary design and implementation illustrated and described herein.

Circuit breakers, at their essence, are electrical switches which is operable to open to protect electrical devices from short circuits, current overloads, and the like that may damage or destroy such electrical equipment. Circuit breakers, depending on their implementation, include complex mechanical and electrical systems. Circuit breakers may be reset, manually or automatically, and used again.

When undesirable conditions, such as high current or high voltage conditions, are detected, the circuit breaker responds by separating the one or more movable electrical contacts of the circuit breaker from the fixed contacts to open the circuit breaker. Generally, this should be done as quickly as possible to avoid or minimize potential damage to electrical equipment that may be destroyed or damaged by the high current or voltage condition. The mechanical parts and systems of a circuit breaker are essential to ensure that the electrical contacts of a circuit breaker will reliably and quickly function. In some circumstances, the circuit breaker will not open or open as quickly as desired. This may be caused by any number of reasons, such as, for example, oxidation, galling, loss of vacuum, and/or insufficient lubrication within the circuit breaker. This may result in increased safety risks.

During operation, such as opening or closing, of the movable electrical contacts, of the circuit breaker, the components of the circuit breaker will vibrate and the vibration signals can be used to monitor condition of the circuit breaker. One or more sensors can be attached to the circuit breaker. Type of the sensor has no limits once it can sense or detect the vibrations of the circuit breaker, and/or its components. The attached positions of the sensors have no limits as long as they do not influence functioning of the circuit breaker.

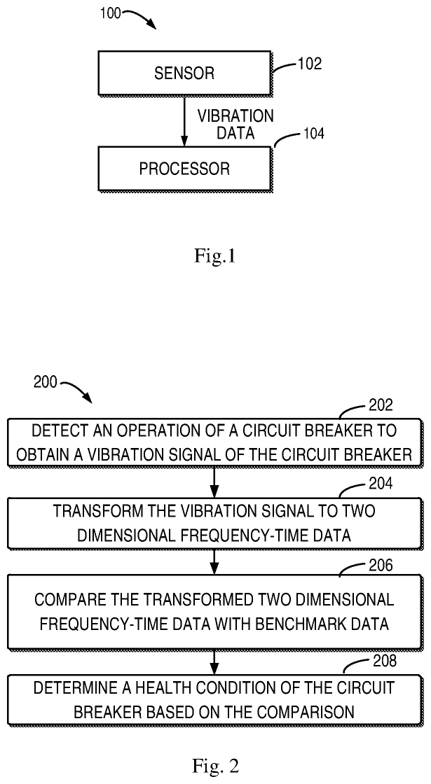

FIG. 1 shows a block diagram of a device 100 for monitoring a circuit breaker in accordance with embodiments of the present disclosure. The device 100 comprises a sensor 102 and at least one processor 104. The sensor 102 is configured to detect vibration data of the circuit breaker during its operation. The at least one processor 104 is communicatively coupled to the sensor 102 and configured to perform the method 200 as described above. In some embodiments, the device 100 is implemented as a separate assembly and is attached to the circuit breaker. In some embodiments, the at least one processor 104 is implemented as a part of the circuit breaker. For example, the controller of the circuit breaker may function as the processor 104 of the device 100.

FIG. 2 illustrates a flowchart of a method 200 for monitoring a circuit breaker in accordance with some example embodiments of the present disclosure. The method 200 can be implemented by, e.g., the device 100 for monitoring a circuit breaker, to efficiently and accurately carry out condition monitoring of the circuit breaker.

At block 202, one or more vibration signals of the circuit breaker are detected by one or more sensors. When the circuit breaker operates, for example, open or close, the circuit breaker vibrates. The sensor may be operable to detect the vibration signals of the circuit breaker for respective operations. In some embodiments, a plurality of sensors is arranged in proper positions of the circuit breaker. The unreliable vibration signals may be excluded. This can improve the reliability of vibration signals.

In some embodiments, the sensor may respond to an activation signal from a controller to detect vibration signals of the circuit breaker. The detected vibration signals are sent to the controller and are stored therein for use in determining the conditions of the circuit breaker.

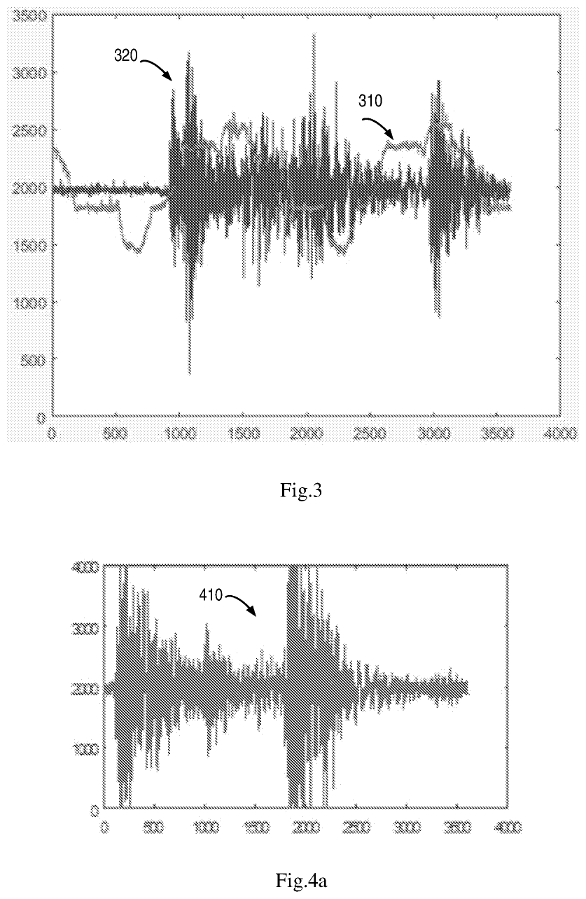

In some embodiments, as shown in FIG. 3, the vibration signal may be represented as one-dimensional data of the vibration amplitude over time. The signals may be analog or digital signals. Merely for ease of discussion, some embodiments will be described with digital signals as an example. It is to be understood, however, that this is not limited and the analog signals can also be used.

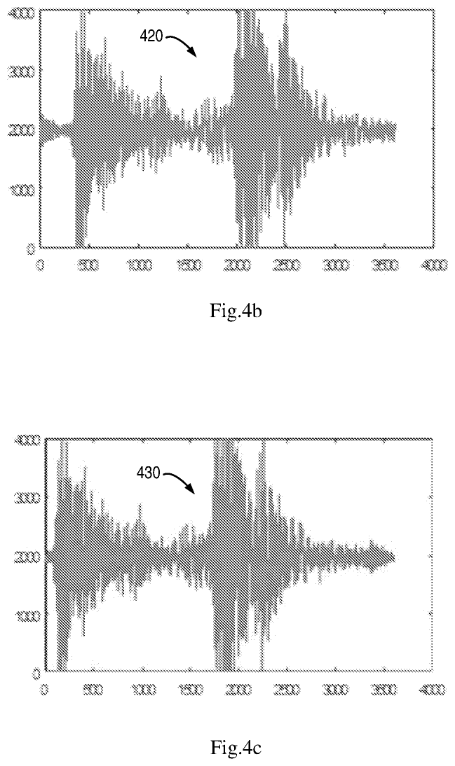

In some circumstance, the vibration signals may contain error data or may have time delay. For example, the error data may be resulted from various reasons, such as communication errors, sensor errors, and mechanical defectives of the circuit breaker. In this case, the vibration signals may be processed to remove the error data from the original vibration signals. As for the signals with time delay even when the shapes of vibration curves are quite similar, such signals can lead to big variations. Such data may lead to wrong condition determination. Two typical data processing methods are described to delete error data or synchronize vibration signals with reference to FIG. 3 and FIGS. 4a-4c hereinafter. In some embodiments, the vibration signals are good with no error data and/or delay. In this case, processing of vibration signals may be omitted.

At block 204, the detected test vibration signals are transformed into two-dimensional frequency-time data. In some embodiments, a wavelet transform, a Short-time Fourier transform, and a Wigner-Ville distribution, etc., can be used to transform the one-dimensional detected vibration signals into two-dimensional frequency-time data. It is to be understood that the above transform methods are merely illustrative, other proper transform methods may also be used. The essential is to transform the one-dimensional vibration signals into two-dimensional time domain and frequency domain data.

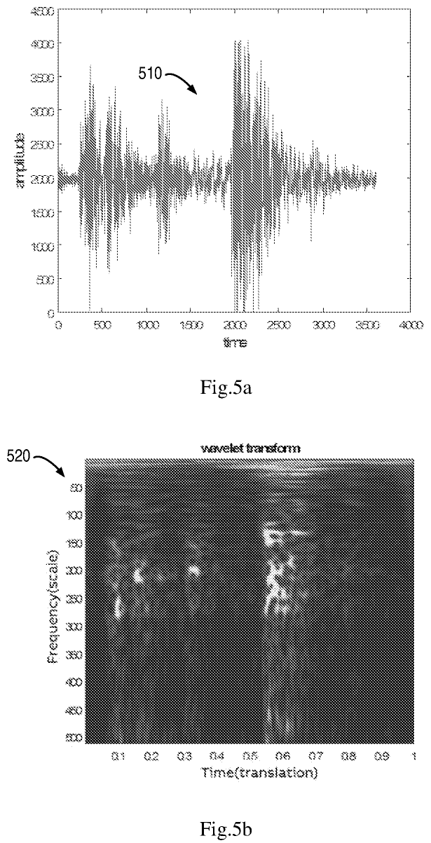

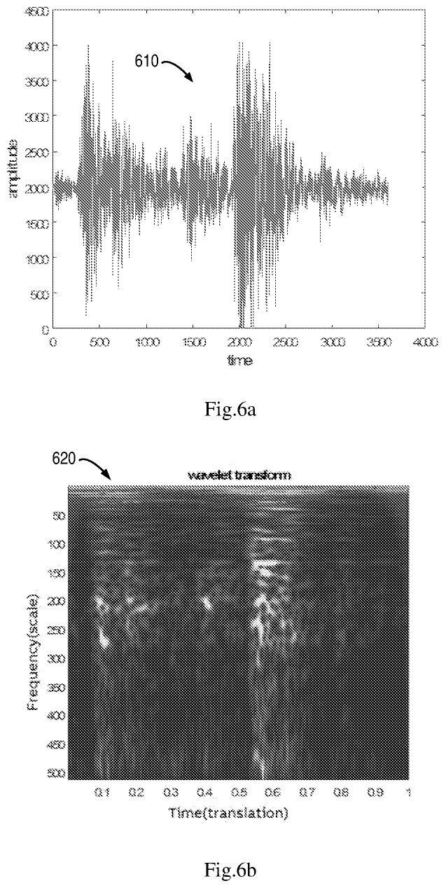

As mentioned above, the detected vibration signals reflect the vibration amplitude change over time during operation of the circuit breaker. By this transformation, the detected vibration signals are represented in both frequency domain and time domain. That is, the frequency component and the time component in the detected vibration signals both are evident in two-dimensional frequency-time data. By this transform, the one-dimensional detected vibration data are transformed into two-dimensional frequency-time data. In this case, various matrix-processing and image processing methods can be used to calculate the similarity between the transformed two-dimensional frequency-time image with the two-dimensional benchmark image. Hereinafter, a wavelet transform is described as an example with reference to FIGS. 5a-6b.

At block 206, the transformed frequency-time data is compared with benchmark data characterizing operations of the circuit breaker. In example embodiments of the present disclosure, the benchmark data are generated in advance. To this end, for example, one-dimensional data of the vibration amplitude over time are detected during operation of a normal circuit breaker. The detected one-dimensional data are transformed to two-dimensional frequency-time data, which can be used as the benchmark data.

In some embodiments, the normal circuit breaker may have a plural of operations, such as open and close, the benchmark data are created for each kind of operation of the circuit breaker. In example embodiments of the present disclosure, the benchmark data are created for a normal circuit breaker. In this case, it is not necessary to create benchmark data for defective or unhealthy circuit breaker. This can reduce processing complexity. It is to be understood that this is merely illustrative. In other embodiments, the benchmark data may be created for a defective device such that the defective type may also be determined. In some embodiments, these benchmark data are stored in a database accessible to a processor of the controller. The database may be local or in the cloud.

In some embodiments, a plurality of vibration signals is used for generating benchmark data. In this case, the benchmark data may be more reliable and the reliability of determination is improved.

At block 208, a health condition of the circuit breaker can be determined based on the comparison. As mentioned above, both the transformed frequency-time data and the benchmark data are two-dimensional. Mathematic methods thus can be used to compare the similarity between the transformed two-dimensional frequency-time data and the benchmark data. In some embodiments, if the transformed two-dimensional frequency-time data are determined to be similar to the benchmark data, the circuit breaker is determined as healthy. If the transformed two-dimensional frequency-time data are determined to be dissimilar to the benchmark data, the circuit breaker is determined as unhealthy or failure. The determined health conditions may be sent the user to prompt the user to take proper actions.

Contrary to conventional condition monitoring approaches which merely consider the vibration amplitude over time of the detected vibration signal, according to embodiments of the present disclosure, both the frequency component and the time component in the detected vibration signals are taken into consideration in determining the condition of the circuit breaker. Consequently, the condition can be determined with high accuracy. Some conditions which cannot be detected by the conventional approaches can now be accurately identified.

In some embodiments, a distance between the two-dimensional frequency-time data and the benchmark data may be calculated. The distance may, for example, be Euclidean distance, Minkowsky distance, and the like. In some embodiments, a correlation coefficient between two-dimensional frequency-time data and the benchmark data may be calculated. A similarity between the two-dimensional frequency-time data and the benchmark data can be depicted by the distance and/or the correlation coefficient between the two images. As these methods are well known mathematic methods, their description are omitted.

In some embodiments, structural similarity (SSIM) may be used for measuring the similarity between the two-dimensional frequency-time image and the benchmark image. For example, the following equation may be used to depict the similarity:

d=1−SSIM=1−l(A,B)^{α}c(A,B)^{β}s(A,B)^{γ} (2)

where A represents the two-dimensional test frequency-time image, B represents the benchmark image, and function l, c, s is to calculate the brightness comparison, contrast comparison, and structure comparison.

$$\begin{matrix}l ( A , B ) = \frac{2 {μ}_{A} {μ}_{B} + {C}_{1}}{{μ}_{A}^{2} + {μ}_{B}^{2} + {C}_{1}} & ( 3 ) \\ c ( A , B ) = \frac{2 {σ}_{A} {σ}_{B} + {C}_{2}}{{σ}_{A}^{2} + {σ}_{B}^{2} + {C}_{2}} & ( 4 ) \\ s ( A , B ) = \frac{{σ}_{AB} + {C}_{3}}{{σ}_{A} {σ}_{B} + {C}_{3}} & ( 5 )\end{matrix}$$

where μ_{A} and σ_{A} represent the mean and variation of image A, σ_{AB} represent the covariance of images A and B, and Cᵢ represents a constant.

In some embodiments, a filtering window may be used to exclude false determination. For example, for each kind of operation of the circuit breaker, such as open and close operation, a plurality of test vibration signals are obtained. In one embodiment, every time when the circuit breaker opens, the sensor may detect or record one vibration signal of the open operation. The vibration signal may be used to determine the condition of the circuit breaker using the inventive method. After a predetermined number of times of operations, a group of determination results are obtained. When the number of certain kind of determination results exceeds certain times, the determination result is considered as the final determination result.

In some embodiments, a threshold may be used when the two-dimensional frequency-time image is compared with the benchmark image. For example, only when a similarity between the two-dimensional frequency-time image and the benchmark image is larger than the threshold, it is determined that the two-dimensional frequency-time image is similar to the benchmark image. The threshold may be set using various methods. In some embodiments, it is set according to user's experience or past statistical data related to the circuit breaker. In some embodiments, it is set according to operation tests of the circuit breaker. In this case, determination reliably can be improved.

It is to be understood that the above image processing methods are merely illustrative rather than limited; any other proper image processing methods may be used to determine the similarity between the two images.

FIG. 3 and FIGS. 4a-4c illustrate schematic views of one-dimensional test vibration signal of the vibration amplitude over time. As shown in FIG. 3, a horizontal axis represents sample times (or time), and a vertical axis represents a vibration amplitude. It is to be understood that the drawings contained herein are not necessarily drawn to scale.

As shown in FIG. 3, the normal sampled signal curve is denoted by reference numeral 320 and the error signal curve is denoted by reference numeral 310. Different from the high frequency of normal vibration signals, these error data are with low frequency. Thus, various waveform filtering methods can be used to filter such error data. In some embodiments, this kind of error data is excluded by counting the number of points larger than normal vibration amplitude and the zero-crossing points. “zero-crossing” herein means waveform or curves in FIG. 3 crossing mean-value of the signals. In such error data, no real vibration is captured, and only a few zero-crossing points exist in the second kind of error data. However, in real vibration curve with high frequency component, there are large amount of zero-crossing points.

In some embodiments, some error data are somewhat constant or like white noise. These error data typically has small variance and can thus by removed using variance calculation. It is to be understood that the filtering methods are merely illustrative; and any other proper method can be used.

As for vibration signals with time delay, synchronization is needed so as to eliminate the delay. Two test vibration signals are shown in FIGS. 4a and 4b which are represented by reference numerals 410 and 420 respectively. The vibration signal curve 410 is used as reference signal curve and the vibration signal curve 420 is the signal curve to be synchronized. There is an obvious time delay in the vibration signal curve 420 compared with the reference signal curve 410. The time delay in the vibration signal curve 420 should be removed. There are many methods for removing the time delay. In one embodiment, a starting point of the vibration signal curve 420 is determined. The vibration signal curve 420 is shifted according to the difference between the calculated start point and a start point of the reference signal curve 410. As shown in FIG. 4c, a vibration signal curves 430 is the vibration signal curves 420 after synchronization.

As mentioned above, there are many mathematic methods, such as a wavelet transform, a Short-time Fourier transform, and a Wigner-Ville distribution, and so on, for transforming the one-dimensional detected vibration data into two-dimensional frequency-time data.

As shown in FIGS. 5a-6b, the wavelet transform is described as one example method for describing the inventive concept of the present disclosure. A test vibration signal is one-dimensional function of time t. The vibration signal function is represented as ƒ(t), and the wavelet transform function wƒ(b,a) is represented by the following equation:

$$wf ( b , a ) = \frac{1}{\sqrt{a}} {\int }_{- x}^{+ x} f ( t ) ψ ( \frac{t - b}{a} ) dt . \qquad ( 1 )$$

where a represents a scale and b represents a translation.

FIGS. 5a and 6a illustrate one-dimensional vibration curves 510, 610 of the vibration amplitude over time of normal and defective circuit breakers in accordance with some example embodiments of the present disclosure respectively. For illustrative purpose, the time or sampling time of a vibration signal is normalized and is represented as translation in wavelet transform, and the frequency of the vibration signal is represented as scale in wavelet transform. Time (or translation) is shown as horizontal axis and frequency (or scale) is shown as a vertical axis. The amplitude of the vibration signal is represented as color value or greyscale value. The Wavelet Transform function may thus be represented by a 2D image in which the signals properties in time domain and frequency domain both are included. FIGS. 5b and 6b illustrates two-dimensional frequency-time images 520, 620 transformed from the vibration signals 510, 610 of FIGS. 5a and 5b by wavelet transform.

As shown in figures, the vibration curves 510, 610 in FIGS. 5a and 6a are very similar and it is very difficult to determine the conditions of the circuit breaker using conventional methods. With the wavelet transform, frequency characteristics of vibration signal at any time point are reflected. The differences between the two images 520, 620 can be determined easily using various methods. For example, as shown in FIGS. 5b and 6b, distribution of bright spots in the two images 520, 620 are clearly different, which reflects the differences of distribution of the frequency components. Since the comparison is performed in an area rather in a line, which makes condition determination of the circuit breaker easier and more comprehensive. Also, the differences between the two signals can be accurately determined using mathematic methods, for example, image processing methods.

With the device 100 for monitoring a circuit breaker, the health condition of the circuit breaker can be reliably and accurately determined in a simply way. All advantages with regard to the method 200 can be analogously achieved, which will not be repeatedly described herein.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device. While various aspects of embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

The present disclosure also provides at least one computer program product tangibly stored on a non-transitory computer readable storage medium. The computer program product includes computer-executable instructions, such as those included in program modules, being executed in a device on a target real or virtual processor, to carry out the process or method as described above with reference to FIG. 2. Generally, program modules include routines, programs, libraries, objects, classes, components, data structures, or the like that perform particular tasks or implement particular abstract data types. The functionality of the program modules may be combined or split between program modules as desired in various embodiments. Machine-executable instructions for program modules may be executed within a local or distributed device. In a distributed device, program modules may be located in both local and remote storage media.

Program code for carrying out methods of the present disclosure may be written in any combination of one or more programming languages. These program codes may be provided to a processor or controller of a general purpose computer, special purpose computer, or other programmable data processing apparatus, such that the program codes, when executed by the processor or controller, cause the functions/operations specified in the flowcharts and/or block diagrams to be implemented. The program code may execute entirely on a machine, partly on the machine, as a stand-alone software package, partly on the machine and partly on a remote machine or entirely on the remote machine or server.

The above program code may be embodied on a machine readable medium, which may be any tangible medium that may contain, or store a program for use by or in connection with an instruction execution system, apparatus, or device. The machine readable medium may be a machine readable signal medium or a machine readable storage medium. A machine readable medium may include but not limited to an electronic, magnetic, optical, electromagnetic, infrared, or semiconductor system, apparatus, or device, or any suitable combination of the foregoing. More specific examples of the machine readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. On the other hand, various features that are described in the context of a single embodiment may also be implemented in multiple embodiments separately or in any suitable sub-combination.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method for monitoring a circuit breaker comprising:
detecting at least one operation of a circuit breaker to obtain at least one vibration signal of the circuit breaker, each vibration signal being represented as one-dimensional data of a vibration amplitude over time during the operation of the circuit breaker;
transforming the vibration signal to two-dimensional frequency-time data;
comparing the transformed frequency-time data with benchmark data characterizing the at least one operation of the circuit breaker; and
determining a health condition of the circuit breaker at least in part based on the comparison.

2. The method according to claim 1, wherein the transforming comprises:
identifying a noise signal component in the vibration signal; and
de-noising the vibration signal by removing the identified noise.

3. The method of claim 1, wherein the transforming comprises:
identifying a delay in the vibration signal; and
synchronizing the vibration signal by removing the delay.

4. The method of claim 1, wherein the transforming comprises applying at least one of the following onto the vibration signal: a wavelet transform, a Short-time Fourier transform, and a Wigner-Ville distribution.

5. The method of claim 1, wherein the comparing comprises:
determining a metric including at least one of the following: a distance between the two-dimensional frequency-time data and the benchmark data, and a correlation coefficient between the two-dimensional frequency-time data and the benchmark data; and
determining a similarity between the two-dimensional frequency-time data and the benchmark data based on the metric.

6. The method of claim 1, wherein the comparing comprises:
processing the two-dimensional frequency-time data using image processing methods, and
determining similarity between the two-dimensional frequency-time data and the benchmark data.

7. The method of claim 1, wherein the benchmark data is generated by:
detecting at least one operation of a normal circuit breaker to obtain at least one normal vibration signal of the circuit breaker;
transforming the at least one normal vibration signals to two-dimensional frequency-time data; and
generating the benchmark data based on the transformed normal frequency-time data.

8. The method of claim 7, wherein the normal operation of the circuit breaker comprises closing and/or opening of the circuit breaker.

9. The method of claim 7, wherein the detecting comprises detecting a plurality of vibration signals; and
wherein the comparing comprises comparing the plurality of vibration signals with the respective benchmark data.

10. The method of claim 9, wherein the determining comprises excluding false determination using a filtering window.

11. A device for monitoring a circuit breaker comprising:
a sensor configured to sense a vibration during operation of the circuit breaker; and
at least one processor communicatively coupled to the sensor and configured to perform the method of claim 1.

12. A computer readable medium having instructions stored thereon, the instructions, when executed on at least one processor, cause the at least one processor to perform the method of claim 1.

13. A computer program product being tangibly stored on a computer readable storage medium and comprising instructions which, when executed on at least one processor, cause the at least one processor to perform the method of claim 1.

14. An Internet of Things (IoT) system comprising:
a circuit breaker; and
the device for circuit breaker condition monitoring of claim 1.
